(19) United States
(12) Patent Application Publication
(10) Pub. No.: US 2024/0098968 A1
(43) Pub. Date: Mar. 21, 2024

(54) MEMORY DEVICE INCLUDING SEMICONDUCTOR ELEMENT

(71) Applicant: Unisantis Electronics Singapore Pte. Ltd., Singapore (SG)

(72) Inventors: Nozomu HARADA, Tokyo (JP); Koji SAKUI, Tokyo (JP)

(21) Appl. No.: 18/470,090

(22) Filed: Sep. 19, 2023

(30) Foreign Application Priority Data
Sep. 21, 2022 (WO) PCT/JP2022/035126

(51) Int. Cl. H10B 12/00; G11C 11/404; G11C 11/4096

(52) U.S. Cl. CPC H10B 12/20; G11C 11/404; G11C 11/4096

(57) ABSTRACT

A first N⁺ layer, a first P layer, a second N⁺ layer, a second P layer, and a third N⁺ layer are formed on a P layer substrate in order from below vertically, a first gate insulating layer surrounds the first P layer, a second gate insulating layer surrounds the second P layer, first and second gate conductor layers surround the first gate insulating layer, and third and fourth gate conductor layers surround the second gate insulating layer. A first wiring layer is connected to the first N⁺ layer, a second wiring layer is connected to the second N⁺ layer, and a third wiring layer is connected to the third N⁺ layer. The first and second gate conductor layers, the second wiring layer, and the third and fourth gate conductor layers have identical shapes in a plan view and are orthogonal to the first and third wiring layers.

### RELATED APPLICATIONS

This application claims priority to PCT/JP2022/035126, filed on Sep. 21, 2022, the entire content of which is incorporated herein by reference.

### BACKGROUND OF THE INVENTION

### 1. Field of the Invention

The present invention relates to a memory device including a semiconductor element.

### 2. Description of the Related Art

Increase of integration density and performance of a memory element has been requested in recent development of large scale integration (LSI) technologies.

Increase in density and performance of a memory element has been advanced. Examples of such memory elements include a dynamic random access memory (DRAM; refer to H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT)”, 2011 Proceeding of the European Solid-State Device Research Conference, (2011), for example) in which capacitors are connected by using a surrounding gate transistor (SGT; refer to Japanese Patent Laid-open No. 2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)) as a select transistor, a phase change memory (PCM; refer to H. S. Philip Wong, S. Raoux, S. Kim, Jiale Liang, J. R. Reifenberg, B. Rajendran, M. Asheghi and K. E. Goodson: “Phase Change Memory”, Proceeding of IEEE, Vol. 98, No. 12, December, pp. 2201-2227 (2010), for example) in which variable resistance elements are connected, a resistive random access memory (RRAM; refer to K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V”, IEDM (2007), for example), and a magneto-resistive random access memory (MRAM; refer to W. Kang, L. Zhang, J. Klein, Y. Zhang, D. Ravelosona, and W. Zhao: “Reconfigurable Codesign of STT-MRAM Under Process Variations in Deeply Scaled Technology”, IEEE Transaction on Electron Devices, pp. 1-9 (2015), for example) in which the orientation of magnetic spin is changed by current to change resistance.

There are also DRAM memory cells (refer to Japanese Patent Laid-open No. 3-171768, M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405-407 (2010), J. Wan, L. Rojer, A. Zaslavsky, and S. Critoloveanu: “A Compact Capacitor-Less High-Speed DRAM Using Field Effect-Controlled Charge Regeneration”, Electron Device Letters, Vol. 35, No. 2, pp. 179-181 (2012), T. Ohsawa, K. Fujita, T. Higashi, Y. Iwata, T. Kajiyama, Y. Asao, and K. Sunouchi: “Memory design using a one-transistor gain cell on SOI”, IEEE JSSC, vol. 37, No. 11, pp. 1510-1522 (2002), T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond”, IEEE IEDM (2006), and E. Yoshida: “A Capacitorless 1T-DRAM Technology Using Gate-Induced Drain-Leakage (GIDL) Current for Low-Power and High-Speed Embedded Memory”, IEEE IEDM (2006)) constituted by one MOS transistor without capacitors. For example, among holes and electrons generated in a channel through an impact ionization phenomenon with source-drain current of a N-channel MOS transistor, some or all of the holes are held in the channel to write logical storage data “1”. Then, the holes are removed from the channel to write logical storage data “0”. In such a memory cell, “1” writing memory cells and “0” writing memory cells randomly exist for a common select word line. When on-voltage is applied to the select word line, voltage of a floating-body channel of any selected memory cell connected to the select word line largely varies due to capacitive coupling between a gate electrode and the channel. The memory cell is required to improve operation margin decrease due to variation in the floating-body channel voltage and improve data holding characteristic decrease due to removal of some of holes as signal electric charge accumulated in the channel.

There are twin-transistor MOS transistor memory elements in which one memory cell is formed in a silicon-on-insulator (SOI) layer by using two MOS transistors (refer to, for example, US2008/0137394 A1, US2003/0111681 A1, and F. Morishita, H. Noda, I. Hayashi, T. Gyohten, M. Oksmoto, T. Ipposhi, S. Maegawa, K. Dosaka, and K. Arimoto: “Capacitorless Twin-Transistor Random Access Memory (TTRAM) on SOT”, IEICE Trans. Electron., Vol. E90-c., No. 4 pp. 765-771 (2007)). In these elements, an N⁺ layer that divides the floating-body channels of the two MOS transistors and functions as a source or a drain is formed in contact with an insulating layer on a substrate side. The N⁺ layer electrically separates the floating-body channels of the two MOS transistors. Holes as signal electric charge are accumulated only in the floating-body channel of one of the MOS transistors. The other MOS transistor serves as a switch for reading the signal holes accumulated in the one MOS transistor. Since holes as signal electric charge are accumulated in the channel of one MOS transistor in this memory cell as well, the memory cell is required to improve operation margin decrease or improve data holding characteristic decrease due to removal of some of holes as signal electric charge accumulated in the channel, similarly to the above-described memory cell constituted by one MOS transistor.

As illustrated in FIG. 6, a dynamic flash memory cell 111 is constituted by a MOS transistor without capacitors (refer to Japanese Patent No. 7057032 and K. Sakui, N. Harada, “Dynamic Flash Memory with Dual Gate Surrounding Gate Transistor (SGT)”, Proc. IEEE IMW, pp. 72-75 (2021)). As illustrated in FIG. 6A, a floating-body semiconductor base material 102 is positioned on a SiO₂ layer 101 of a SOI substrate. An N⁺ layer 103 connected to a source line SL and an N⁺ layer 104 connected to a bit line BL are positioned at both ends of the floating-body semiconductor base material 102. A first gate insulating layer 109a is connected to the N⁺ layer 103 and covers the floating-body semiconductor base material 102, and a second gate insulating layer 109b is connected to the N⁺ layer 104 and the first gate insulating layer 109a through a slit insulating film 110 and covers the floating-body semiconductor base material 102. A first gate conductor layer 105a covers the first gate insulating layer 109a and is connected to a plate line PL, and a second gate conductor layer 105b covers the second gate insulating layer 109b and is connected to a word line WL. The slit insulating film 110 is positioned between the first gate conductor layer 105a and the second gate conductor layer 105b. Accordingly, the memory cell 111 as a dynamic flash memory (DFM) is formed. The source line SL may be connected to the N⁺ layer 104, and the bit line BL may be connected to the N⁺ layer 103.

As illustrated in FIG. 6A, for example, zero voltage is applied to the N⁺ layer 103 and positive voltage is applied to the N⁺ layer 104 so that a first N-channel MOS transistor region provided by the floating-body semiconductor base material 102 covered by the first gate conductor layer 105a is operated as a saturation region, and a second N-channel MOS transistor region provided by the floating-body semiconductor base material 102 covered by the second gate conductor layer 105b is operated as a linear region. As a result, an inversion layer 107b is formed on the entire surface of the second N-channel MOS transistor region without a pinch-off point. The inversion layer 107b formed below the second gate conductor layer 105b connected to the word line WL functions as an effective drain of the first N-channel MOS transistor region. As a result, electric field is maximum in a boundary channel region between the first N-channel MOS transistor region and the second N-channel MOS transistor region, and an impact ionization phenomenon occurs in this region. As illustrated in FIG. 6B, among electrons and holes generated through the impact ionization phenomenon, the electrons are removed from the floating-body semiconductor base material 102 but some or all of these holes 106 are held in the floating-body semiconductor base material 102. In this manner, memory write operation is performed. This state is allocated as logical storage data “1”.

As illustrated in FIG. 6C, for example, positive voltage is applied to the plate line PL, zero voltage is applied to the word line WL and the bit line BL, and negative voltage is applied to the source line SL so that the holes 106 are removed from the floating-body semiconductor base material 102 to perform erase operation. This state is allocated as logical storage data “0”. At data reading, voltage applied to the first gate conductor layer 105a connected to the plate line PL is set to be higher than threshold voltage for logical storage data “1” and lower than threshold voltage for logical storage data “0”. Accordingly, such a characteristic is obtained that no current flows when voltage of the word line WL is set to be high at reading of logical storage data “0” as illustrated in FIG. 6D. With this characteristic, the operation margin is significantly expanded as compared to the memory cell. In this memory cell, since channels in the first and second N-channel MOS transistor regions with gates that are the first gate conductor layer 105a connected to the plate line PL and the second gate conductor layer 105b connected to the word line WL are connected to each other through the floating-body semiconductor base material 102, voltage variation of the floating-body semiconductor base material 102 when select pulsed voltage is applied to the word line WL is largely suppressed. Accordingly, the problems of the above-described memory cell, such as operation margin decrease or data hold characteristic decrease due to removal of some of holes as signal electric charge accumulated in a channel, are largely improved. Further characteristic improvement and increase of integration density will be required for such a memory element in the future.

Further increase of integration density of a dynamic flash memory cell is required.

### SUMMARY OF THE INVENTION

To solve the above-described problem, a memory device including a semiconductor element according to the present invention includes a first memory cell configured to perform data write operation, data read operation, and data erase operation with voltage applied to each of a first impurity layer, a first gate conductor layer, a second gate conductor layer, a second impurity layer, a third gate conductor layer, a fourth gate conductor layer, and a third impurity layer.

The first impurity layer, a first semiconductor layer, the second impurity layer, a second semiconductor layer, and the third impurity layer are formed on a substrate in order from below in a vertical direction. A first gate insulating layer contacts a side surface of the first semiconductor layer. A second gate insulating layer contacts a side surface of the second semiconductor layer. The first gate conductor layer contacts a lower side surface of the first gate insulating layer. The second gate conductor layer contacts an upper side surface of the first gate insulating layer at a position separated from and adjacent to the first gate conductor layer. The third gate conductor layer contacts a lower side surface of the second gate insulating layer. The fourth gate conductor layer contacts an upper side surface of the second gate insulating layer at a position separated from and adjacent to the third gate conductor layer. A first wiring layer is connected to the first impurity layer. A second wiring layer is connected to the second impurity layer. A third wiring layer is connected to the third impurity layer. The first to fourth gate conductor layers and the second wiring layer have identical shapes in a plan view (first invention).

According to a second invention, in the above-described first invention, the first and third wiring layers are orthogonal to a direction in which the first to fourth gate conductor layers and the second wiring layer extend in a plan view.

According to a third invention, in the above-described first invention, the first wiring layer partially or entirely surrounds an outer circumferential part of a bottom part of the first semiconductor layer in a plan view and is connected to the first impurity layer.

According to a fourth invention, in the above-described first invention, the first wiring layer contacts the first impurity layer at a bottom part.

According to a fifth invention, in the above-described first invention, the second wiring layer penetrates through a middle part of the second impurity layer.

According to a sixth invention, in the above-described first invention, the first to fourth gate conductor layers and the second wiring layer have identical two-dimensional shapes in a plan view and are connected to an adjacent memory cell.

According to a seventh invention, in the above-described first invention, the first gate conductor layer and the fourth gate conductor layer have equal lengths in the vertical direction, and the second gate conductor layer and the third gate conductor layer have equal lengths in the vertical direction.

According to an eighth invention, in the above-described first invention, the first wiring layer is connected to a first bit line, the second wiring layer is connected to a first common source line, the third wiring layer is connected to a second bit line, one of the first and second gate conductor layers is connected to a first plate line, and the other is connected to a first word line, the third gate conductor layer is connected to a second word line or a second plate line, the second word line being the same as a signal line to which the second gate conductor layer is connected, and the fourth gate conductor layer is connected to a second word line or a second plate line, the second word line being the same as a signal line to which the first gate conductor layer is connected.

According to a ninth invention, in the above-described first invention, the data write operation is executed to generate pairs of electrons and holes in one or both of the first and second semiconductor layers through an impact ionization phenomenon or gate induced drain leakage current with voltage applied to each of the first impurity layer, the first gate conductor layer, the second gate conductor layer, the second impurity layer, the third gate conductor layer, the fourth gate conductor layer, and the third impurity layer, and retain signal electric charge of the electrons or holes in the one or both of the first and second semiconductor layers, and the data erase operation is executed to remove the signal electric charge from the one or both of the first and second semiconductor layers with voltage applied to each of the first impurity layer, the first gate conductor layer, the second gate conductor layer, the second impurity layer, the third gate conductor layer, the fourth gate conductor layer, and the third impurity layer.

According to a tenth invention, in the above-described first invention, a second memory cell having the same section as the first memory cell in the horizontal and vertical directions is provided on the first memory cell in the vertical direction, and the third impurity layer and the third wiring layer connected to the third impurity layer are shared between the first and second memory cells.

According to an eleventh invention, in the above-described first invention, one or both of pairs of the first and fourth gate conductor layers and the second and third gate conductor layers are separated in two in the vertical direction.

According to a twelfth invention, in the above-described first invention, the first to fourth gate conductor layers are each separated in two and have identical shapes in an overlapping manner in a plan view.

### BRIEF DESCRIPTION OF THE DRAWINGS

FIGS. 1A, 1B, and 1C are structural diagrams of a two-tier dynamic flash memory cell according to a first embodiment;

FIGS. 2A, 2B, and 2C are structural diagrams of a two-tier dynamic flash memory cell according to a second embodiment;

FIGS. 3A, 3B, and 3C are structural diagrams of a two-tier dynamic flash memory cell according to a third embodiment;

FIGS. 4A, 4B, and 4C are structural diagrams of a two-tier dynamic flash memory cell according to a fourth embodiment;

FIGS. 5A and 5B are structural diagrams of a four-tier dynamic flash memory cell according to a fifth embodiment; and

FIGS. 6A, 6B, 6C and 6D are diagrams for description of a dynamic flash memory of a conventional example.

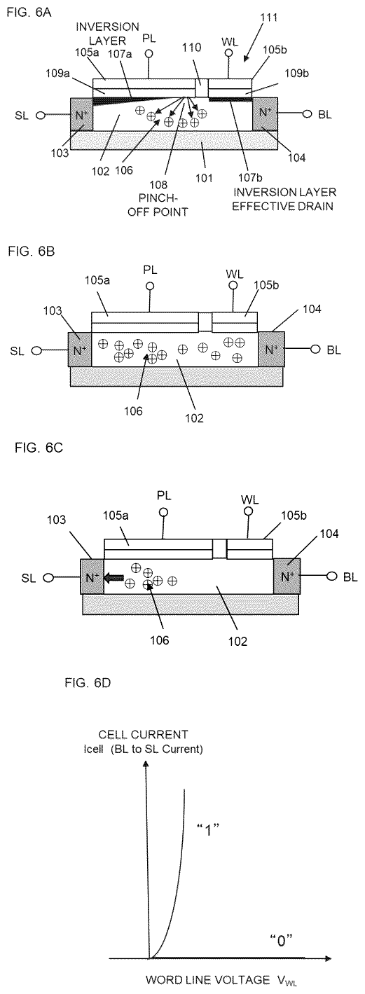

### DETAILED DESCRIPTION OF THE PREFERRED EMBODIMENTS

A memory device (hereinafter referred to as dynamic flash memory) including a semiconductor element according to each embodiment of the present invention will be described below with reference to the accompanying drawings.

### First Embodiment

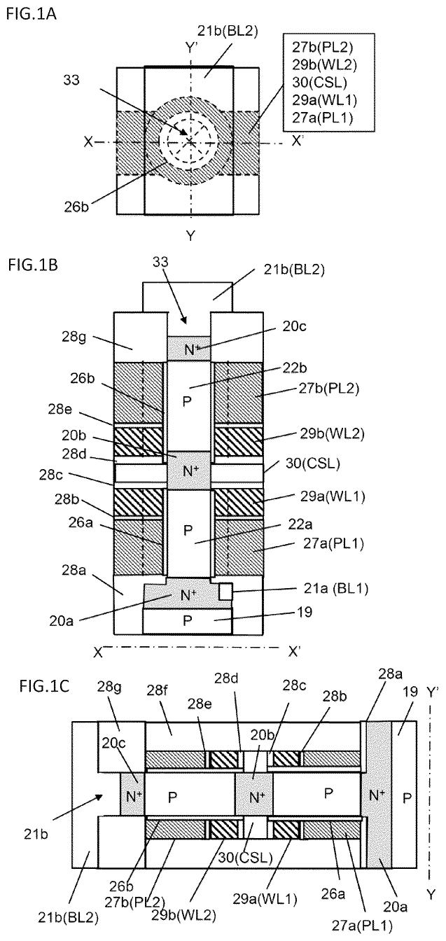

The structure of a two-tier dynamic flash memory cell according to a first embodiment of the present invention will be described below with reference to FIGS. 1A to 1C. FIG. 1A illustrates a plan view of the two-tier dynamic flash memory cell. FIG. 1B illustrates a cross-sectional view taken along line X-X′ in FIG. 1A. FIG. 1C illustrates a cross-sectional view taken along line Y-Y′ in FIG. 1A. In an actual dynamic flash memory, such two-tier dynamic flash memory cells are two-dimensionally arrayed in a large number.

An N⁺ layer 20a (an example of “first impurity layer” in the claims) is positioned on a P layer substrate 19 (an example of “substrate” in the claims). A P layer 22a (example of “first semiconductor layer” in the claims), an N⁺ layer 20b (an example of “second impurity layer” in the claims), a P layer 22b (an example of “second semiconductor layer” in the claims), and an N⁺ layer 20c (an example of “third impurity layer” in the claims) are positioned in order from below on the N⁺ layer 20a and shaped as a column. A wiring layer 21a (an example of “first wiring layer” in the claims) made of metal or alloy is connected to the N⁺ layer 20a. An insulating layer 28a surrounds the P layer substrate 19, the N⁺ layer 20a, and the wiring layer 21a. A first gate insulating layer 26a (an example of “first gate insulating layer” in the claims) surrounds the P layer 22a, and a second gate insulating layer 26b (an example of “second gate insulating layer” in the claims) surrounds the P layer 22b. A first gate conductor layer 27a (an example of “first gate conductor layer” in the claims) surrounds the lower side of the first gate insulating layer 26a. An insulating layer 28b is positioned on the first gate conductor layer 27a. A second gate conductor layer 29a (an example of “second gate conductor layer” in the claims) contacts the insulating layer 28b and surrounds the upper side of the first gate insulating layer 26a. A wiring layer 30 (an example of “second wiring layer” in the claims) contacts the N⁺ layer 20b and sandwiched between insulating layers 28c and 28d in the vertical direction. A third gate conductor layer 29b (an example of “third gate conductor layer” in the claims) surrounds the lower side of the second gate insulating layer 26b. A fourth gate conductor layer 27b (an example of “fourth gate conductor layer” in the claims) surrounds the upper side of the second gate insulating layer 26b at a position separated from the third gate conductor layer 29b with an insulating layer 28e interposed therebetween. An insulating layer 28g covers the entire configuration. A wiring layer 21b (an example of “third wiring layer” in the claims) is connected to the N⁺ layer 20c through a contact hole 33 opened at the insulating layer 28g on the N⁺ layer 20c. The P layers 22a and 22b desirably have equal lengths in the vertical direction. Similarly, the first gate conductor layer 27a and the fourth gate conductor layer 27b desirably have equal lengths in the vertical direction. Similarly, the second gate conductor layer 29a and the third gate conductor layer 29b desirably have equal lengths in the vertical direction.

In the dynamic flash memory cell illustrated in FIGS. 1A to 1C, data write operation is performed to generate pairs of electrons and holes in one or both of the P layers 22a and 22b through an impact ionization phenomenon or gate induced drain leakage current by applying predetermined voltage to each of the N⁺ layer 20a, the first gate conductor layer 27a, the second gate conductor layer 29a, the N⁺ layer 20b, the third gate conductor layer 29b, the fourth gate conductor layer 27b, and the N⁺ layer 20c, and retain the holes as signal electric charge in the one or both of the P layers 22a and 22b. Then, data erase operation is performed to remove the holes as signal electric charge from the one or both of the P layers 22a and 22b by applying predetermined voltage to each of the N⁺ layer 20a, the first gate conductor layer 27a, the second gate conductor layer 29a, the N⁺ layer 20b, the third gate conductor layer 29b, the fourth gate conductor layer 27b, and the N⁺ layer 20c.

In FIGS. 1A to 1C, a first dynamic flash memory cell is constituted by the N⁺ layer 20a, the P layer 22a, the N⁺ layer 20b, the first gate insulating layer 26a, the first gate conductor layer 27a, and the second gate conductor layer 29a. A second dynamic flash memory cell is constituted by the N⁺ layer 20b, the P layer 22b, the N⁺ layer 20c, the second gate insulating layer 26b, the third gate conductor layer 29b, and the fourth gate conductor layer 27b. The N⁺ layer 20b is shared between the first and second dynamic flash memory cells.

In the first dynamic flash memory cell, the wiring layer 21a connected to the N⁺ layer 20a is connected to a first bit line BL1. The first gate conductor layer 27a is connected to a first plate line PL1. The second gate conductor layer 29a is connected to a first word line WL1. The wiring layer 30 connected to the N⁺ layer 20b is connected to a common source line CSL. In the second dynamic flash memory cell, the wiring layer 30 connected to the N⁺ layer 20b is connected to the common source line CSL. The third gate conductor layer 29b is connected to a second word line WL2. The fourth gate conductor layer 27b is connected to a second plate line PL2. The wiring layer 21b connected to the N⁺ layer 20c is connected to a second bit line BL2. As described above, the wiring layer 30 connected to the N⁺ layer 20b serves as the common source line CSL for the first and second dynamic flash memory cells.

In FIGS. 1A to 1C, the wiring layer 21a connected to the first bit line BL1 and the wiring layer 21b connected to the second bit line BL2 extend in the direction of line Y-Y′ in a plan view. The first gate conductor layer 27a connected to the first plate line PL1, the second gate conductor layer 29a connected to the first word line WL1, the wiring layer 30 connected to the common source line CSL, the third gate conductor layer 29b connected to the second word line WL2, and the fourth gate conductor layer 27b connected to the second plate line PL2 extend in the direction of line X-X′ orthogonal to line Y-Y in a plan view. The first gate conductor layer 27a, the second gate conductor layer 29a, the wiring layer 30, the third gate conductor layer 29b, and the fourth gate conductor layer 27b formed in order from below in an overlapping manner have identical shapes in a plan view.

Accordingly, a two-tier dynamic flash memory cell in which the two dynamic flash memory cells are connected to each other in the vertical direction by sharing the N⁺ layer 20b connected to the common source line CSL is formed.

The first gate conductor layer 27a and the fourth gate conductor layer 27b may be each separated in two in the vertical direction. In this case, separated gate conductor layers of the first and second dynamic flash memory cells, which are closer to the N⁺ layer 20b may have equal lengths in the vertical direction. The second gate conductor layer 29a and the third gate conductor layer 29b may be each separated in two in the vertical direction. In this case, separated gate conductor layers of the first and second dynamic flash memory cells, which are closer to the N⁺ layer 20b may have equal lengths in the vertical direction. Each separated gate conductor layer may be driven out of synchronization. With this configuration as well, the present memory cell is normally operated. Moreover, the first gate conductor layer 27a and the fourth gate conductor layer 27b may be each separated in two in the vertical direction, and each separated gate conductor layer may be separated in two in the horizontal direction. In this case, the separated gate conductor layers are formed in an overlapping manner in a plan view.

The first to fourth gate conductor layers 27a, 27b, 29a, and 29b may be each separated in two in a plan view. In this case, the separated first to fourth gate conductor layers 27a, 27b, 29a, and 29b are desirably formed with identical shapes in an overlapping manner in a plan view. Each separated gate conductor layer may be driven out of synchronization. With this configuration as well, the present memory cell is normally operated.

The first gate conductor layer 27a and the fourth gate conductor layer 27b may be connected to the word lines WL1 and WL2, and the second gate conductor layer 29a and the third gate conductor layer 29b may be connected to the plate lines PL1 and PL2. With this configuration as well, normal dynamic flash memory operation is performed.

The wiring layer 21a formed on the N⁺ layer 20a on one side of the P layer 22a in a plan view and extending in the direction of line Y-Y′ may be formed on the N⁺ layer 20a on each side of the P layer 22a in a plan view.

The present embodiment has characteristics as described below.

(1) In formation of the above-described two-tier dynamic flash memory cell, the first gate conductor layer 27a connected to the first plate line PL1, the second gate conductor layer 29a connected to the first word line WL1, the wiring layer 30 connected to the common source line CSL, the third gate conductor layer 29b connected to the second word line WL2, and the fourth gate conductor layer 27b connected to the second plate line PL2, which have identical shapes in a plan view, are formed on the P layer substrate 19. This indicates that the first gate conductor layer 27a, the second gate conductor layer 29a, the wiring layer 30, the third gate conductor layer 29b, and the fourth gate conductor layer 27b can be formed by batch through single execution of a lithography process and an etching process. Accordingly, integration density increase and cost reduction of the dynamic flash memory are achieved.

(2) The N⁺ layer 20b serves as a common source line (CSL) of the two dynamic flash memory cells. Accordingly, the structure of the two-tier dynamic flash memory cell can be simplified. Accordingly, integration density increase and cost reduction of the dynamic flash memory are achieved.

### Second Embodiment

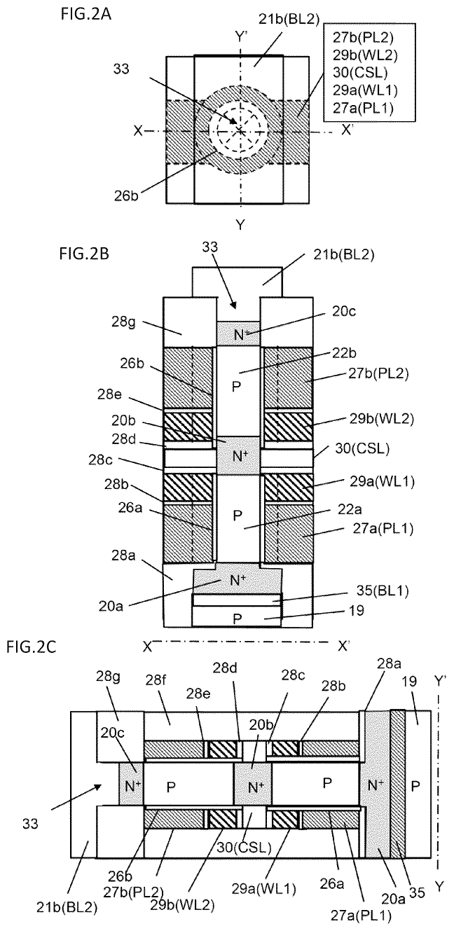

The structure of a two-tier dynamic flash memory cell according to a second embodiment of the present invention will be described below with reference to FIGS. 2A to 2C. FIG. 2A illustrates a plan view of the two-tier dynamic flash memory cell. FIG. 2B illustrates a cross-sectional view taken along line X-X′ in FIG. 2A. FIG. 2C illustrates a cross-sectional view taken along line Y-Y′ in FIG. 2A. In an actual dynamic flash memory, such two-tier dynamic flash memory cells are two-dimensionally arrayed in a large number.

In FIGS. 1A to 1C, the wiring layer 21a connected to the first bit line BL1 is formed on each side of the N⁺ layer 20a. However, in FIGS. 2A to 2C, a wiring layer 35 connected to the first bit line BL1 is formed below the N⁺ layer 20a and on the P layer substrate 19.

The present embodiment has characteristics as described below.

In the first embodiment, highly accurate lithography and etching processes are needed to form the wiring layer 21a. However, in the present embodiment, the wiring layer 35 can be simultaneously formed through the process of forming the P layer substrate 19 and the N⁺ layer 20a. Accordingly, integration density increase and cost reduction of the two-tier dynamic flash memory cell are achieved.

### Third Embodiment

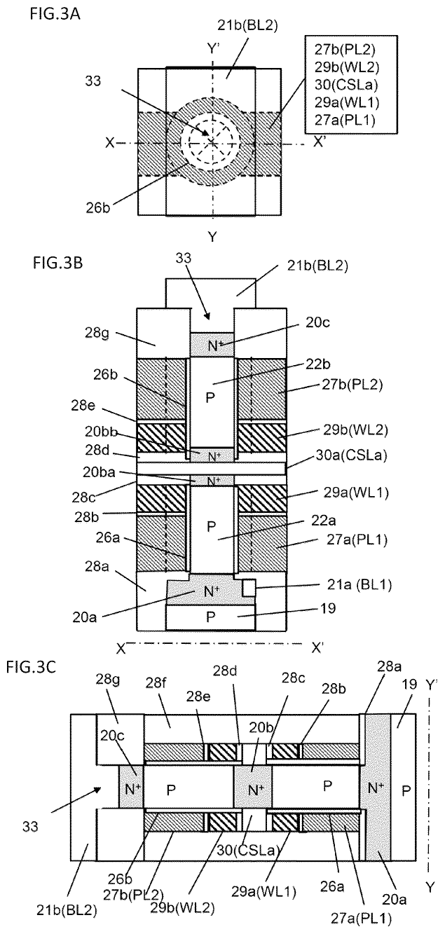

The structure of a two-tier dynamic flash memory cell according to a third embodiment of the present invention will be described below with reference to FIGS. 3A to 3C. FIG. 3A illustrates a plan view of the two-tier dynamic flash memory cell. FIG. 3B illustrates a cross-sectional view taken along line X-X′ in FIG. 3A. FIG. 3C illustrates a cross-sectional view taken along line Y-Y′ in FIG. 3A. In an actual dynamic flash memory, such two-tier dynamic flash memory cells are two-dimensionally arrayed in a large number.

In FIGS. 1A to 1C, the wiring layer 30 surrounding the side surface of the N⁺ layer 20b, extending in the direction of line X-X′, and connected to the common source line CSL is formed. However, in FIGS. 3A to 3C, a wiring layer 30a vertically dividing the N⁺ layer 20b into two N⁺ layers 20ba and 20bb, extending in the direction of line X-X′, and connected to a common source line CSLa is formed.

According to the present embodiment, voltage can be uniformly applied to sections of the N⁺ layers 20ba and 20bb through the wiring layer 30a. This contribute to an effect of reducing characteristic variation among two-dimensionally arrayed two-tier dynamic flash memory cells.

### Fourth Embodiment

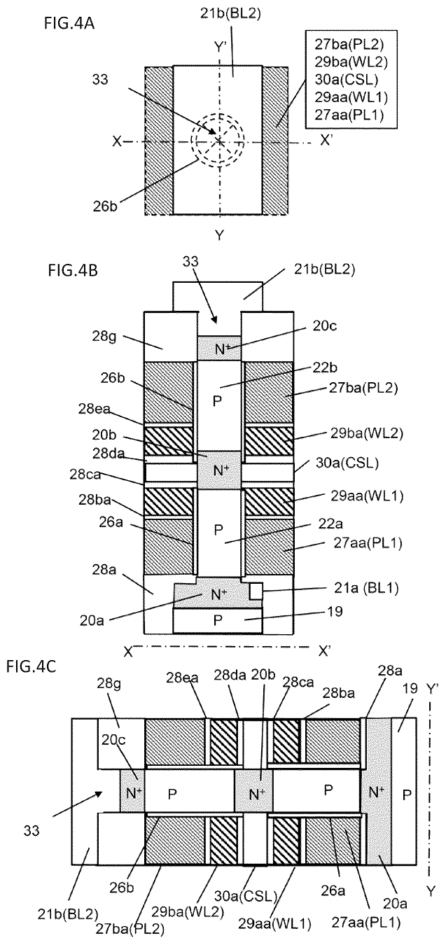

The structure of a two-tier dynamic flash memory cell according to a fourth embodiment of the present invention will be described below with reference to FIGS. 4A to 4C. FIG. 4A illustrates a plan view of the two-tier dynamic flash memory cell. FIG. 4B illustrates a cross-sectional view taken along line X-X′ in FIG. 4A. FIG. 4C illustrates a cross-sectional view taken along line Y-Y′ in FIG. 4A. In an actual dynamic flash memory, such two-tier dynamic flash memory cells are two-dimensionally arrayed in a large number.

In the two-tier dynamic flash memory cell illustrated in FIGS. 1A to 1C, the first gate conductor layer 27a, the second gate conductor layer 29a, the wiring layer 30, the third gate conductor layer 29b, and the fourth gate conductor layer 27b each surround the first gate insulating layer 26a or the second gate insulating layer 26b and extend in the direction of line X-X′. These shapes in a plan view correspond to a case of connection to the gate conductor layers of the first plate lines PL1, the first word lines WL1, the common source lines CSL, the second plate lines PL2, and the second word lines WL2 of memory cells surrounding outer circumferential parts of the P layers 22a and 22b and adjacent in the direction of line X-X′. However, FIGS. 4A to 4C correspond to a case in which the two-tier dynamic flash memory cell is connected to adjacent two-tier dynamic flash memory cells in both directions of line X-X′ and line Y-Y′ in a plan view through a first gate conductor layer 27aa connected to the first plate lines PL1 of the adjacent two-tier dynamic flash memory cells, a second gate conductor layer 29aa connected to the first word lines WL1 thereof, the wiring layer 30a connected to the common source lines CSL thereof, a third gate conductor layer 29ba connected to the second plate lines PL2 thereof, and a fourth gate conductor layer 27ba connected to the second word lines WL2 thereof. In this case, the first gate conductor layer 27aa, the second gate conductor layer 29aa, the wiring layer 30a, the third gate conductor layer 29ba, and the fourth gate conductor layer 27ba are formed in connection with the adjacent two-tier dynamic flash memory cells in a plan view.

According to the present embodiment, the first gate conductor layer 27aa, the second gate conductor layer 29aa, the wiring layer 30a, the third gate conductor layer 29ba, and the fourth gate conductor layer 27ba can be formed without more minute fabrication than that for the first gate conductor layer 27a, the second gate conductor layer 29a, the wiring layer 30, the third gate conductor layer 29b, and the fourth gate conductor layer 27b in the first embodiment illustrated in FIGS. 1A to 1C.

### Fifth Embodiment

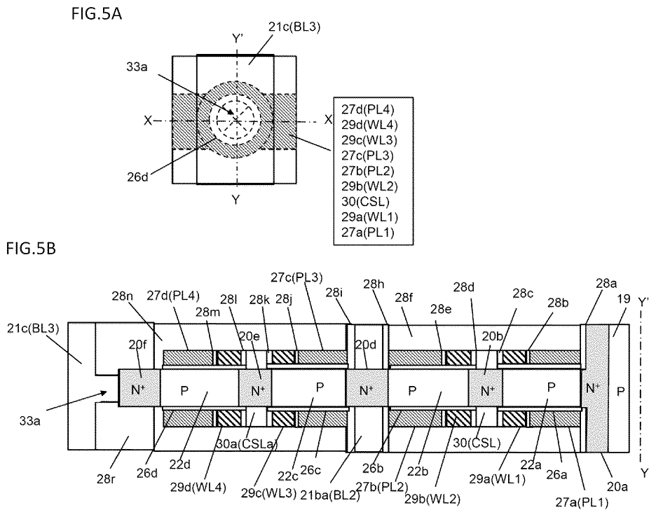

The structure of a four-tier dynamic flash memory cell according to a fifth embodiment of the present invention will be described below with reference to FIGS. 5A and 5B. FIG. 5A illustrates a plan view of the four-tier dynamic flash memory cell. FIG. 5B illustrates a cross-sectional view taken along line Y-Y′ in FIG. 5A. In an actual dynamic flash memory, such four-tier dynamic flash memory cells are two-dimensionally arrayed in a large number.

In the dynamic flash memory cell illustrated in FIGS. 5A and 5B, a second two-tier dynamic flash memory cell is connected to the first two-tier dynamic flash memory cell illustrated in FIGS. 1A to 1C. The first two-tier dynamic flash memory includes the first dynamic flash memory cell constituted by the N⁺ layer 20a, the P layer 22a, the N⁺ layer 20b, the first gate insulating layer 26a, the first gate conductor layer 27a, and the second gate conductor layer 29a, and also includes the second dynamic flash memory cell constituted by the N⁺ layer 20b, the P layer 22b, an N⁺ layer 20d, the second gate insulating layer 26b, the third gate conductor layer 29b, and the fourth gate conductor layer 27b. The second two-tier dynamic flash memory cell includes a third dynamic flash memory cell constituted by the N⁺ layer 20d, a P layer 22c, an N⁺ layer 20e, a third gate insulating layer 26c, a fifth gate conductor layer 27c, and a sixth gate conductor layer 29c, and also includes a fourth dynamic flash memory cell constituted by the N⁺ layer 20e, a P layer 22d, an N⁺ layer 20f, a fourth gate insulating layer 26d, a seventh gate conductor layer 29d, and an eighth gate conductor layer 27d. The P layers 22a, 22b, 22c, and 22d desirably have equal lengths in the vertical direction. Similarly, the first gate conductor layer 27a, the fourth gate conductor layer 27b, the fifth gate conductor layer 27c, and the eighth gate conductor layer 27d desirably have equal lengths in the vertical direction. Similarly, the second gate conductor layer 29a, the third gate conductor layer 29b, the sixth gate conductor layer 29c, and the seventh gate conductor layer 29d desirably have equal lengths in the vertical direction.

A wiring layer 21ba surrounds the N⁺ layer 20d and extends in the direction of line Y-Y′. Insulating layers 28h and 28i are positioned below and above the wiring layer 21ba. An insulating layer 28j is positioned between the fifth gate conductor layer 27c and the sixth gate conductor layer 29c. An insulating layer 28m is positioned between the seventh gate conductor layer 29d and the eighth gate conductor layer 27d. An insulating layer 28r surrounds a contact hole 33a and the N⁺ layer 20f.

The first gate conductor layer 27a, the second gate conductor layer 29a, the wiring layer 30, the third gate conductor layer 29b, the fourth gate conductor layer 27b, the fifth gate conductor layer 27c, the sixth gate conductor layer 29c, the seventh gate conductor layer 29d, and the eighth gate conductor layer 27d formed in order from below in an overlapping manner have identical shapes in a plan view.

In the third dynamic flash memory cell of the second two-tier dynamic flash memory cell, the wiring layer 21ba connected to the N⁺ layer 20d is connected to the second bit line BL2. The fifth gate conductor layer 27c is connected to a third plate line PL3. The sixth gate conductor layer 29c is connected to a third word line WL3. The wiring layer 30a connected to the N⁺ layer 20e is connected to the common source line CSLa. In the fourth dynamic flash memory cell of the second two-tier dynamic flash memory cell, the wiring layer 30a connected to the N⁺ layer 20e is connected to the common source line CSLa. The seventh gate conductor layer 29d is connected to a fourth word line WL4. The eighth gate conductor layer 27d is connected to a fourth plate line PL4. A wiring layer 21c connected to the N⁺ layer 20f through the contact hole 33a is connected to a third bit line BL3. As described above, the wiring layer 30a connected to the N⁺ layer 20e is connected as a source of the third and fourth dynamic flash memory cells to the common source line CSLa. The wiring layer 21ba connected to the second bit line BL2 serves as a bit line wiring layer common to the second and third dynamic flash memory cells.

Accordingly, the second two-tier dynamic flash memory cell in which the third and fourth dynamic flash memory cells are connected to each other in the vertical direction by sharing the N⁺ layer 20e connected to the common source line CSLa is formed. Then, the second two-tier dynamic flash memory cell is connected to the first two-tier dynamic flash memory cell. Accordingly, a four-tier dynamic flash memory cell is constituted by the first and second two-tier dynamic flash memory cells.

The present embodiment has characteristics as described below.

In the four-tier dynamic flash memory cell, the first gate conductor layer 27a, the second gate conductor layer 29a, the wiring layer 30, the third gate conductor layer 29b, the fourth gate conductor layer 27b, the fifth gate conductor layer 27c, the sixth gate conductor layer 29c, the wiring layer 30a, the seventh gate conductor layer 29d, and the eighth gate conductor layer 27d have identical shapes in a plan view. Accordingly, the four-tier dynamic flash memory cell has the same cell area as the two-tier dynamic flash memory cell described above with reference to FIGS. 1A to 1C. Accordingly, integration density increase of the dynamic flash memory is achieved.

### OTHER EMBODIMENTS

In FIGS. 1A to 1C, the P layers 22a and 22b and the N⁺ layers 20a, 29b, and 20c may be made of silicon (Si) or any other semiconductor material. This also applies to any other embodiment according to the present invention. The semiconductor material of the P layers 22a and 22b may be different from the semiconductor material of the N⁺ layers 20a, 29b, and 20c.

The first gate insulating layer 26a may be different between a region surrounded by the first gate conductor layer 27a and a region surrounded by the second gate conductor layer 29a. Similarly, the second gate insulating layer 26b may be different between a region surrounded by the third gate conductor layer 29b and a region surrounded by the fourth gate conductor layer 27b. This also applies to any other embodiment according to the present invention.

In “1” writing, pairs of electrons and holes may be generated by using gate induced drain leakage (GIDL) current as disclosed in E. Yoshida. “A Capacitorless 1T-DRAM Technology Using Gate-Induced Drain-Leakage (GIDL) Current for Low-Power and High-Speed Embedded Memory”, IEEE IEDM (2006), and a floating body FB may be filled with the generated holes. This also applies to any other embodiment according to the present invention.

Dynamic flash memory operation is performed also with a structure in which the polarity of conduction type of each of the N⁺ layers 20a, 20b, and 20c and the P layers 22a and 22b is inverted in FIGS. 1A to 1C. In this case, majority carriers are electrons since the P layers 22a and 22b are changed to N layers. Thus, electrons generated through impact ionization serve as signal electric charge in memory operation. This also applies to any other embodiment according to the present invention.

Although one dynamic flash memory cell is described above with reference to FIGS. 1A to 1C, the P layers 22a and 22b may be two-dimensionally arrayed in a square lattice shape, an oblique lattice shape, a zigzag shape, a sawtooth shape, or any other optional disposition to form a memory block region. This also applies to any other embodiment.

The above description with reference to FIGS. 5A and 5B is made on a configuration in which four dynamic flash memory cells are stacked on the P layer substrate 19, but three dynamic flash memory cells or five or more dynamic flash memory cells may be stacked as long as the condition that wiring layers connected to plate lines, word lines, and source lines have identical shapes in a plan view is satisfied. This also applies to any other embodiment.

For example, a silicon oxide insulator (SOI) or a well-structure substrate may be used as the P layer substrate 19 in FIGS. 1A to 1C as long as the material functions as a substrate. This also applies to any other embodiment.

The shapes of the P layers 22a and 22b in a plan view are illustrated as circles in FIGS. 1A to 1C. However, the shapes of the P layers 22a and 22b in a plan view may be any other shapes such as rectangles or ellipses. This also applies to any other embodiment.

In the above description with reference to FIGS. 1A to 1C, the first gate conductor layer 27a, the second gate conductor layer 29a, the wiring layer 30, the third gate conductor layer 29b, and the fourth gate conductor layer 27b have identical shapes in a plan view, but they have difference in plan-view shape due to, for example, difference in side etching length among the layers, which occurs when etching is simultaneously performed by using one mask material layer. This also applies to any other embodiment.

In FIGS. 1A to 1C, the first gate conductor layer 27a, the second gate conductor layer 29a, the third gate conductor layer 29b, and the fourth gate conductor layer 27b may be each constituted by a plurality of layers in a horizontal section. This also applies to any other embodiment.

The present invention can have various embodiments and modifications without departing from the spirit and scope in a broad sense of the present invention. Each above-described embodiment is only intended to describe an example of the present invention and does not limit the scope of the present invention. Any above-described example and modification may be optionally combined. Some constituent components of the above-described embodiments may be omitted as appropriate within the technological idea of the present invention.

With a memory device including a semiconductor element according to the present invention, it is possible to obtain a dynamic flash memory as a highly dense and high performance memory device.

What is claimed is:

1. A memory device including a semiconductor element, the semiconductor element including a first memory cell configured to perform data write operation, data read operation, and data erase operation with voltage applied to each of a first impurity layer, a first gate conductor layer, a second gate conductor layer, a second impurity layer, a third gate conductor layer, a fourth gate conductor layer, and a third impurity layer, wherein
the first impurity layer, a first semiconductor layer, the second impurity layer, a second semiconductor layer, and the third impurity layer are formed on a substrate in order from below in a vertical direction,
a first gate insulating layer contacts a side surface of the first semiconductor layer,
a second gate insulating layer contacts a side surface of the second semiconductor layer,
the first gate conductor layer contacts a lower side surface of the first gate insulating layer,
the second gate conductor layer contacts an upper side surface of the first gate insulating layer at a position separated from and adjacent to the first gate conductor layer,
the third gate conductor layer contacts a lower side surface of the second gate insulating layer,
the fourth gate conductor layer contacts an upper side surface of the second gate insulating layer at a position separated from and adjacent to the third gate conductor layer,
a first wiring layer is connected to the first impurity layer,
a second wiring layer is connected to the second impurity layer,
a third wiring layer is connected to the third impurity layer, and
the first to fourth gate conductor layers and the second wiring layer have identical shapes in a plan view.

2. The memory device including the semiconductor element according to claim 1, wherein the first and third wiring layers are orthogonal to a direction in which the first to fourth gate conductor layers and the second wiring layer extend in a plan view.

3. The memory device including the semiconductor element according to claim 1, wherein the first wiring layer partially or entirely surrounds an outer circumferential part of a bottom part of the first semiconductor layer in a plan view and is connected to the first impurity layer.

4. The memory device including the semiconductor element according to claim 1, wherein the first wiring layer contacts the first impurity layer at a bottom part.

5. The memory device including the semiconductor element according to claim 1, wherein the second wiring layer penetrates through a middle part of the second impurity layer.

6. The memory device including the semiconductor element according to claim 1, wherein the first to fourth gate conductor layers and the second wiring layer have identical two-dimensional shapes in a plan view and are connected to an adjacent memory cell.

7. The memory device including the semiconductor element according to claim 1, wherein
the first gate conductor layer and the fourth gate conductor layer have equal lengths in the vertical direction, and
the second gate conductor layer and the third gate conductor layer have equal lengths in the vertical direction.

8. The memory device including the semiconductor element according to claim 1, wherein
the first wiring layer is connected to a first bit line,
the second wiring layer is connected to a first common source line,
the third wiring layer is connected to a second bit line,
one of the first and second gate conductor layers is connected to a first plate line, and the other is connected to a first word line,
the third gate conductor layer is connected to a second word line or a second plate line, the second word line being the same as a signal line to which the second gate conductor layer is connected, and
the fourth gate conductor layer is connected to a second word line or a second plate line, the second word line being the same as a signal line to which the first gate conductor layer is connected.

9. The memory device including the semiconductor element according to claim 1, wherein
the data write operation is executed to generate pairs of electrons and holes in one or both of the first and second semiconductor layers through an impact ionization phenomenon or gate induced drain leakage current with voltage applied to each of the first impurity layer, the first gate conductor layer, the second gate conductor layer, the second impurity layer, the third gate conductor layer, the fourth gate conductor layer, and the third impurity layer, and retain signal electric charge of the electrons or holes in the one or both of the first and second semiconductor layers, and
the data erase operation is executed to remove the signal electric charge from the one or both of the first and second semiconductor layers with voltage applied to each of the first impurity layer, the first gate conductor layer, the second gate conductor layer, the second impurity layer, the third gate conductor layer, the fourth gate conductor layer, and the third impurity layer.

10. The memory device including the semiconductor element according to claim 1, wherein
a second memory cell having the same section as the first memory cell in horizontal and vertical directions is provided on the first memory cell in the vertical direction, and
the third impurity layer and the third wiring layer connected to the third impurity layer are shared between the first and second memory cells.

11. The memory device including the semiconductor element according to claim 1, wherein one or both of pairs of the first and fourth gate conductor layers and the second and third gate conductor layers are separated in two in the vertical direction.

12. The memory device including the semiconductor element according to claim 1, wherein the first to fourth gate conductor layers are each separated in two and have identical shapes in an overlapping manner in a plan view.
